(19) United States
(12) Patent Application Publication
(10) Pub. No.: US 2025/0067942 A1
(43) Pub. Date: Feb. 27, 2025

(54) ELECTRICAL-OPTICAL CONVERSION WITH 3D STACKED PHOTONIC CHIPLET(S) IN SUBSTRATE

(71) Applicant: Lightmatter, Inc., Boston, MA (US)

(72) Inventors: Kuang Liu, Queen Creek, AZ (US); Clifford Chao, Palo Alto, CA (US); Krishna Bharath, Portland, OR (US); Darius Bunandar, Boston, MA (US)

(73) Assignee: Lightmatter, Inc., Boston, MA (US)

(21) Appl. No.: 18/809,928

(22) Filed: Aug. 20, 2024

Related U.S. Application Data
(60) Provisional application No. 63/520,766, filed on Aug. 21, 2023.

(51) Int. Cl. G02B 6/42; H01L 23/00; H01L 23/498; H01L 25/16

(52) U.S. Cl. CPC G02B 6/4202; G02B 6/4243; G02B 6/4291; H01L 23/49816; H01L 23/49827; H01L 24/16; H01L 25/167; H01L 2224/16225; H01L 2924/1425

(57) ABSTRACT

Described herein are packages in which photonic chiplets are disposed in recesses defined on an underlying substrate. Positioning chiplets in this way allows short trace lengths between the electrical chips and the optical converters, V-groove fiber assemblies that can be attached along any direction of a photonic chiplet (north-south and/or west-east) and easy access to the electrical chips for power and signals. A package may include a substrate having a recess defined near an edge of the substrate, a photonic chiplet disposed in the recess, an electrical chiplet disposed at least in part on the photonic chiplet, and a fiber optically coupled to the photonic chiplet at the edge of the substrate. The electrical chiplet may be disposed in part on the photonic chiplet and in part on the top surface of the substrate.

### CROSS-REFERENCE TO RELATED APPLICATION

This application claims the benefit under 35 U.S.C. § 119(e) of U.S. Provisional Application Ser. No. 63/520,766, filed on Aug. 21, 2023, under Attorney Docket No. L0858.70077US00 and entitled “ELECTRICAL-OPTICAL CONVERSION WITH 3D STACKED PHOTONIC CHIPLET(S) IN SUBSTRATE,” which is hereby incorporated herein by reference in its entirety.

### BACKGROUND

Photonic chips, also known as photonic integrated circuits (PICs), are devices that integrate multiple photonic functions (such as light manipulation and detection) on a single chip. These chips use photons, the fundamental particles of light, to perform operations that would traditionally be done by electronic circuits using electrons. Photonic chips can transmit data at speeds much faster than electronic chips, making them ideal for applications in high-speed internet and telecommunications. Photonic chips represent a significant advancement in the field of photonics and are poised to play a crucial role in the future of computing, communication, and various other technologies.

### BRIEF SUMMARY

Some embodiments relate to a package comprising a substrate having a recess defined near an edge of the substrate; a photonic chiplet disposed in the recess; an electrical chiplet disposed at least in part on the photonic chiplet; and a fiber optically coupled to the photonic chiplet at the edge of the substrate.

In some embodiments, a portion of the photonic chiplet overhangs the substrate.

In some embodiments, the package further comprises one or more connections coupling a top surface of the substrate to a top surface of the photonic chiplet.

In some embodiments, the photonic chiplet comprises a through silicon via (TSV) coupled to the substrate.

In some embodiments, the electrical chiplet is disposed in part on the photonic chiplet and in part on the substrate.

In some embodiments, the photonic chiplet has a top surface that is less than 30 mm×40 mm.

Some embodiments relate to a package comprising: a substrate having a recess; a photonic chiplet disposed in the recess; a photonic interposer disposed on the substrate; and an electrical chiplet disposed at least in part on the photonic interposer, wherein the photonic chiplet is coupled to the photonic interposer electrically or optically.

In some embodiments, the photonic interposer covers at least partially the photonic chiplet.

In some embodiments, the package further comprises a first fiber coupled to the photonic interposer and a second fiber coupled to the photonic chiplet.

In some embodiments, the first fiber and the second fiber extend in directions orthogonal to each other.

In some embodiments, the photonic chiplet is optically coupled to the photonic interposer via evanescent coupling.

In some embodiments, the photonic chiplet is electrically coupled to the photonic 20 interposer via metal bumps.

Some embodiments relate to a package comprising a substrate having a first recess defined near a first edge of the substrate and a second recess defined near a second edge of the substrate; a first photonic chiplet disposed in the first recess and a second photonic chiplet disposed in the second recess; and a first fiber optically coupled to the first photonic chiplet at the first edge of the substrate and a second fiber optically coupled to the second photonic chiplet at the second edge of the substrate.

In some embodiments, the first edge is orthogonal to the second edge.

In some embodiments, the package further comprises an electrical chiplet disposed at least in part on the first photonic chiplet.

In some embodiments, the electrical chiplet is disposed at least in part on the second photonic chiplet.

In some embodiments, the package further comprising a first V-groove, disposed in the first recess, coupling the first fiber to the first photonic chiplet; and a second V-groove, disposed in the second recess, coupling the second fiber to the second photonic chiplet.

In some embodiments, a portion of the first photonic chiplet overhangs the substrate.

In some embodiments, the first photonic chiplet comprises a through silicon via (TSV) coupled to the substrate.

In some embodiments, the package further comprises one or more connections coupling a top surface of the substrate to a top surface of the first photonic chiplet.

### BRIEF DESCRIPTION OF DRAWINGS

Various aspects and embodiments of the application will be described with reference to the following figures. It should be appreciated that the figures are not necessarily drawn to scale. Items appearing in multiple figures are indicated by the same reference number in the figures in which they appear.

FIG. 1A is a cross sectional side view of a package including a photonic chiplet disposed in a recess of a substrate, in accordance with some embodiments.

FIG. 1B is a top view of a substrate having multiple photonic chiplets disposed in respective recesses of the substrate, in accordance with some embodiments.

FIG. 2 is a cross sectional side view of another package including a photonic chiplet disposed in a recess of a substrate, in accordance with some embodiments.

FIG. 3 is an isometric view of a substrate, where wire bonds couple the top surface of the substrate to the top surface of a photonic chiplet, in accordance with some embodiments.

FIG. 4 is an isometric view of a substrate, where a bridging circuit board couples the top surface of the substrate to the top surface of a photonic chiplet, in accordance with some embodiments.

FIG. 5 is an isometric view of a substrate, where a metal bus bar couples the top surface of the substrate to the top surface of a photonic chiplet, in accordance with some embodiments.

FIG. 6 is a cross sectional side view of a package including a photonic interposer and a photonic chiplet disposed in a recess of a substrate, in accordance with some embodiments.

FIG. 7 is a cross sectional side view of another package including a photonic interposer and a photonic chiplet disposed in a recess of a substrate, in accordance with some embodiments.

FIG. 8 is a top view of a package including a photonic interposer and a photonic chiplet disposed in a recess of a substrate, in accordance with some embodiments.

### DETAILED DESCRIPTION

Described herein are techniques for packaging electrical and photonic chips in ways that improve upon conventional solutions in terms of power efficiency, signal integrity and system complexity. The inventors have recognized and appreciated that conventional electrical-photonic packages present significant trade-offs between power consumption and complexity. On one hand are co-packaged optics (CPO) solutions, where a photonic chip and an electrical chip sit side-by-side, either on a substrate or an electrical interposer. While this is a relatively simple solution that does not require use of through silicon vias (TSVs) and that enables V-groove fiber attaches in any direction of the photonic chip, long metal traces (typically several millimeters long) are generally required between the electrical chips and the photonic chips to support communication between those chips. Such long traces require serializer-deserializer (SERDES) units, which are power hungry. On the other hand are 3D-stacked photonic interposer solutions, where a photonic interposer positioned under electrical chips provides access to optical fibers. While this is a more flexible solution with superior optical power and performance relative to CPO solutions, V-groove fiber attaches are limited to one dimension (either in the north-south direction or in the west-east direction, but not in both directions). This limits the overall bandwidth coming out of the package.

The inventors have developed a packaging approach that overcomes the trade-offs described above. The approach developed by the inventors and described herein relies on positioning photonic chiplets in respective recesses defined on an underlying substrate. Positioning chiplets in this way allows short trace lengths between the electrical chips and the optical converters, V-groove fiber assemblies that can be attached along any direction of a photonic chiplet (north-south as well as west-east) and easy access to the electrical chips for power and signals. These photonic chips are identified as “chiplets” to indicate that they are generally smaller than conventional photonic interposers. For example, conventional photonic interposers are often fabricated by stitching together several reticles using stepper machines. By contrast, photonic chiplets of the types described therein may be of the size of, or even smaller than, a reticle (e.g., the top surface may be less than 30 mm×40 mm or 30 mm×35 mm or 30 mm×30 mm or 28 mm×38 mm or 28 mm×35 mm or 28 mm×30 mm or 26 mm×33 mm, though other dimensions are also possible). The bandwidth coming out of a package can be significantly increased relative to conventional approaches by co-packaging several photonic chiplets on a common substrate, where each chiplet is disposed on a respective recess. Each recess may be disposed near an edge of the substrate, which allows direct optical access to the chiplets via edge-coupled optical fibers. In this way, each edge of a substrate may provide optical access to the package, thereby increasing bandwidth density.

The packages described herein present a further advantage over conventional implementations in that electrical access to the electrical chips may be provided using solutions other than TSVs. Solutions based on TSVs are not always practical from a fabrication standpoint because they require complicated and costly manufacturing steps. Positioning a photonic chip in a recess allows the electrical chiplet to be disposed on the photonic chip only partially (in part on the photonic chip and in part on the underlying substrate), as opposed to entirely as in conventional photonic interposers. This arrangement allows electrical access to the electrical chip directly from the substrate, without having to pass through the photonic chip. As such, the requirement for TSVs may be removed.

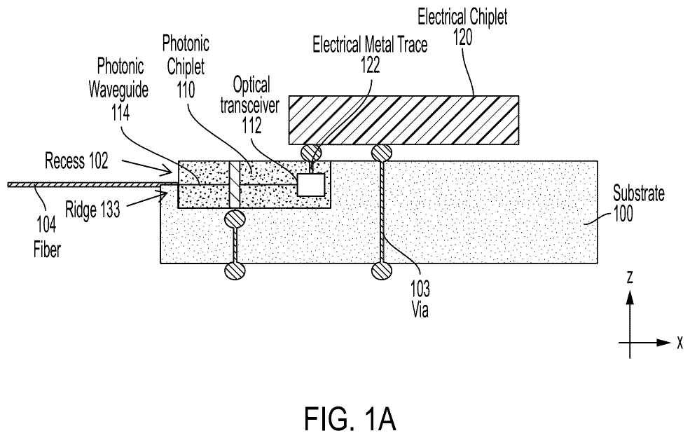

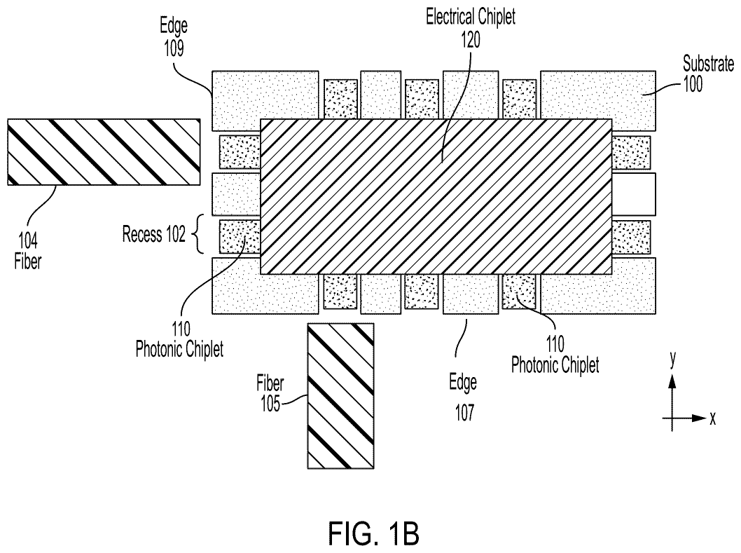

FIG. 1A is a cross sectional side view of a package including a photonic chiplet 110 disposed in a recess 102 of a substrate 100 and an electrical chiplet 120. Photonic chiplet 110 may include photonic circuitry configured to manipulate, route and detect light. For example, photonic chiplet 110 may include modulators, waveguides, switches, couplers and photodetectors, among other possible photonic devices. In some embodiments, photonic chiplet 110 is implemented using silicon photonics. Electrical chiplet 120 may include a memory (e.g., a high bandwidth memory), a processor, a graphic processing unit, or an electronic router, among other possible electronic systems. Photonic chiplet 110 provides access to electrical chiplet 120 from devices placed outside the package in the optical domain.

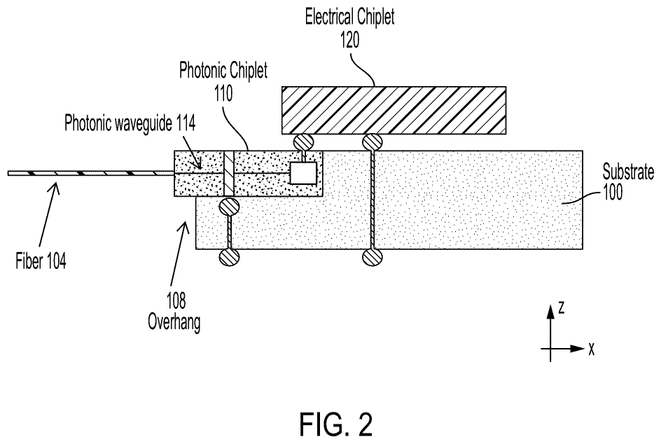

Recess 102 may be near an edge of substrate 100, thus allowing fiber 104 to be edge coupled to photonic chiplet 110 when chiplet 110 is in the recess. For example, recess 102 may extend to the outer perimeter of the substrate; as such, a portion of the outer perimeter may be recessed relative to the top surface of substrate 100. The depth of recess 102 may be chosen so that the top surface of photonic chiplet 110 and the top surface of substrate 100 are co-planar. In the example of FIG. 1A, a ridge 133 is formed in correspondence with the outer edge of substrate 100. Ridge 133 may be defined by partially etching a portion of the edge of substrate 100, thereby creating a raised portion of semiconductor at the edge of recess 102. The height of ridge 133 may be chosen so that fiber 104, when resting on ridge 133, optically aligns with photonic waveguide 114. In those embodiments including a ridge 133, recess 102 may still be viewed as being near an edge of substrate 100 in that recess 102 allows fiber 104 to be edge coupled to photonic chiplet 110 when chiplet 110 is in recess 102 despite the presence of ridge 133. In other embodiments, ridge 133 may be omitted and photonic chiplet 110 may be positioned to have an edge flush with the outer edge of substrate 100. Alternatively, photonic chiplet 110 may be positioned to have an edge extending over the outer edge of substrate 100 (as described below in connection with FIG. 2). Yet alternatively, photonic chiplet 110 may be positioned to have an edge extending inside the outer edge of substrate 100.

FIG. 1A shows an example implementation with a single photonic chiplet (110) and a single electrical chiplet (120), although there may be any number of photonic chiplets and any number of electrical chiplets. In some embodiments, a plurality of electrical chiplets may connect to a plurality of photonic chiplets. Alternatively, a single electrical chiplet may connect to multiple photonic chiplets in the substrate beneath (as discussed below in connection with FIG. 1B). Yet alternatively, a single photonic chiplet in the substrate may connect to multiple electrical chiplets above.

Electrical chiplet 120 is disposed in part on the photonic chiplet 110 and in part on the top surface of substrate 100. This arrangement enables relatively short connections between photonic chiplet 110 and electrical chiplet 120 (through electrical metal trace 122), which is beneficial because it reduces the impedance of the connection. By contrast, connections based on wire bonds are significantly longer, leading to increased impedance and as a result lower bandwidth. Additionally, this arrangement allows powering of the electrical chiplet directly from the substrate (through via 103). This may be beneficial in that it may remove the requirement for TSVs in the photonic chiplet.

An optical transceiver 112 formed within photonic chiplet 110 enables communication between the photonic chiplet and the electrical chiplet. The optical transceiver includes an electro-optical converter (e.g., a modulator) and an optical-electrical converter (e.g., a photodetector). Internally, transceiver 112 is optically coupled to photonic waveguide 114 (or a network of photonic waveguides) which provides access to optical fiber 104. Fiber 104 is edge coupled to the photonic chiplet via a V-groove, for example. A small trench on the side of the photonic chiplet may provide sufficient room to fit a V-groove assembly.

As noted above, packages of the types described herein may include multiple photonic chiplets and/or multiple electrical chiplets. In some embodiments, a package may include multiple photonic chiplets for each electrical chiplet included in the package. Having multiple photonic chiplets per electrical chiplet increases the overall bandwidth coming out of the electrical chiplet, thus increasing data rate. The photonic chiplets may be disposed along the entire perimeter of the package, thereby providing as much bandwidth as possible. It should be noted, however, that only a portion of the perimeter may have photonic chiplets, as not all embodiments are limited in that respect.

FIG. 1B is a top view of a package including an electrical chiplet 120 and multiple photonic chiplets 110. Each photonic chiplet 110 may include a transceiver coupling to electrical chiplet 120. As shown, this implementation allows edge coupling to the photonic chiplets in the north-south direction (parallel to the y-axis) as well as in the west-east direction (parallel to the x-axis). For example, a first fiber 105 is coupled to a chiplet at edge 107 and a second fiber 104 is coupled to another chiplet at edge 109. Because edge 107 is orthogonal to edge 109, the fibers extend in directions that are orthogonal to each other. Although only two fibers are shown in FIG. 1B, in some embodiments there may be a fiber for each photonic chiplet of the package or a subset of the photonic chiplets of the package.

In the implementation of FIG. 1B, each photonic chiplet 110 is disposed in a respective recess 102, although in other implementations recesses may be shared by multiple photonic chiplets. In one example, a single continuous recess defined along the perimeter of substrate 100 may accommodate all the photonic chiplets. In another example, there may be multiple recesses defined along the perimeter of substrate 100, each recess able to accommodate one or more photonic chiplets. As noted above, positioning photonic chiplets in recesses defined near the perimeter of the substrate promotes efficient coupling using optical fibers.

An alternative implementation, shown in FIG. 2, involves the photonic chiplet(s) disposed in a recess of a substrate with a portion of the chiplet that is overhanging. In this example, a portion of chiplet 110 is suspended in correspondence to the region identified as overhang 108 in FIG. 2. Assembling the package so that photonic chiplet 110 overhangs as shown in FIG. 2 provides further room for a fiber near the edge of the package, allowing the fiber to be disposed as close as possible to the edge of photonic chiplet 110. This may further improve optical coupling between waveguide 114 and fiber 104. As in the implementation of FIG. 1A, multiple photonic chiplets and/or multiple electrical chiplets may be included in the package.

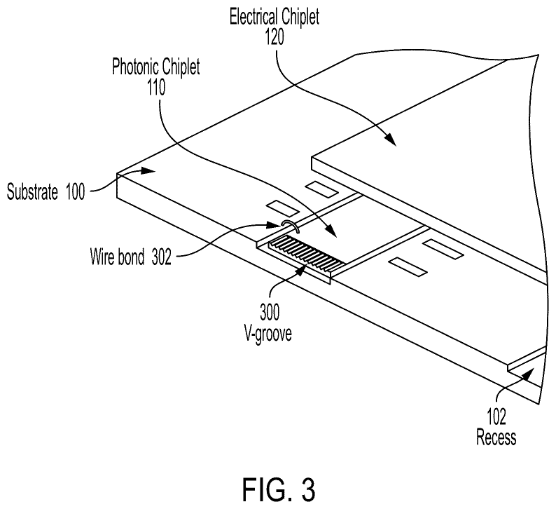

In some embodiments, TSVs within the photonic chiplets are replaced with connections that electrically couple the top surface of the substrate to the top surface of a photonic chiplet. Examples of such connections include wire bonds, bridging circuit boards and stamped metal bus bars, as shown in the examples of FIGS. 3-5.

In the example of FIG. 3, one or more wire bonds 302 are used to provide electrical access from the substrate to the photonic chiplet and vice versa. A wire bond 302 extends from the top surface of substrate 100 to the top surface of photonic chiplet 110, and carry electrical signals between substrate 100 and photonic chiplet 110 and/or power from substrate 100 to photonic chiplet 110. The electrical signals may be encoded with data to be exchanged between electrical chiplet 120 and photonic chiplet 110. As further illustrated in FIG. 3, one or more V-grooves 300 may be employed to facilitate fiber edge coupling to photonic chiplet 110. A V-groove 300 may be formed by etching away (e.g., using isotropic etching) a portion of the edge of photonic chiplet 110, and may be sufficiently wide to accommodate a fiber in it (not shown in FIG. 3). In some embodiments, photonic chiplet 110 may include multiple V-grooves to accommodate multiple fibers (e.g., one fiber per V-groove). V-groove(s) 300 may be employed whether or not the package includes a ridge 133 of the types described in connection with FIG. 1A. FIG. 3 further illustrates an additional recess 102. Although the additional recess 102 is empty in this example, one or more photonic chiplets may be positioned in the recess to increase the overall bandwidth with which the package communicates with other devices.

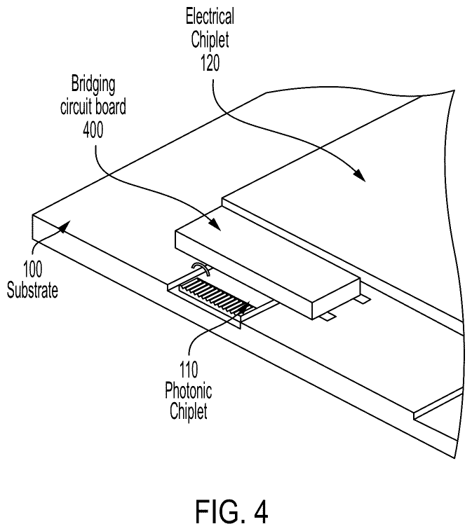

In the example of FIG. 4, a bridging circuit board 400 electrically connects the top substrate of the substrate to the top surface of the photonic chiplet, thereby providing electrical access. As described in connection with wire bond(s) 300, bridging circuit board 400 may carry electrical signals between substrate 100 and photonic chiplet 110 and/or power from substrate 100 to photonic chiplet 110. Bridging circuit board 400 may be implemented using a printed circuit board (PCB) or another type of electronic substrate, and may have conductive traces formed on the bottom surface (the surface facing the top surface of substrate 100) thereof. The conductive traces place pads defined on the top surface of substrate 100 in electrical communication with pads defined on the top surface of photonic chiplet 100. As in the example of FIG. 3, V-groove(s) may be used to facilitate fiber coupling.

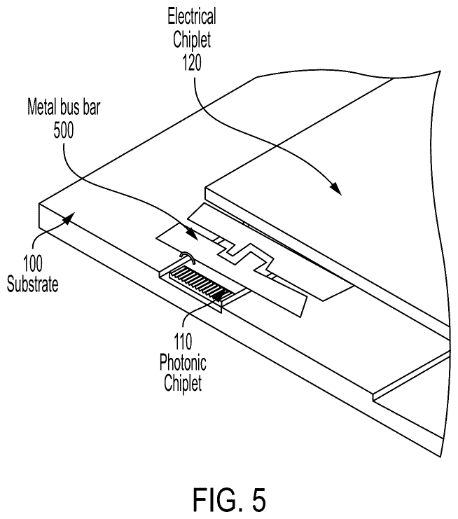

In the example of FIG. 5, metal bus bars 500 electrically connect the top substrate of the substrate to the top surface of the photonic chiplet, thereby providing electrical access. As described in connection with wire bond(s) 300 and bridging circuit board 400, metal bus bar 500 may carry electrical signals between substrate 100 and photonic chiplet 110 and/or power from substrate 100 to photonic chiplet 110. Metal bus bars 500 may be stamped as discrete conductive elements, each of which places one or more pads defined on the top surface of substrate 100 in electrical communication with one or more pads defined on the top surface of photonic chiplet 100. The conductive elements may be shaped to place certain pads formed on the top surface of photonic chiplet 110 in communication with the substrate, while avoiding placing other pads formed on the top surface of photonic chiplet 110 in communication with the substrate (e.g., to avoid improper connections and/or shorts). For example, a metal bus bar may be shaped to have at least one segmented edge (e.g., with cut away portions and projections as shown in FIG. 5) or at least one curved edge. As in the example of FIG. 3, V-groove(s) may be used to facilitate fiber coupling.

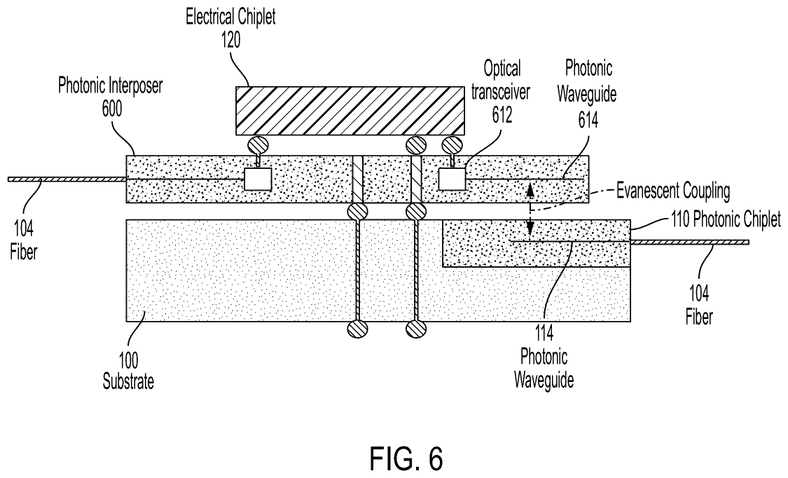

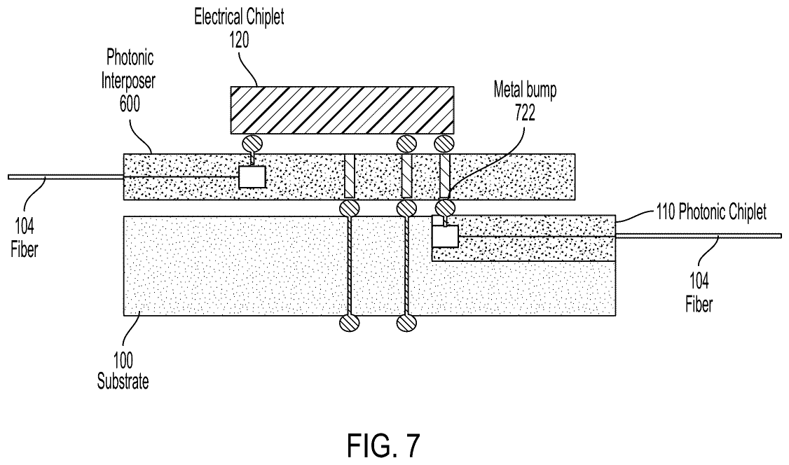

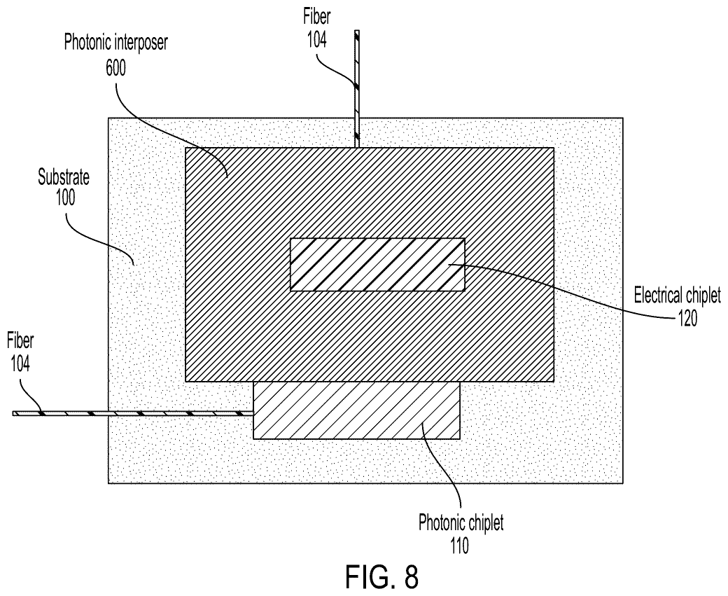

In some embodiments, the arrangements described herein may be used in connection with photonic interposers. Conventional photonic interposer packages provide access to the interposer from only one direction. The photonic interposer packages described herein, however, provide optical access from multiple directions. This is because optical access to the photonic interposer can be provided directly as well as by means of photonic chiplets disposed in recesses of a substrate (as shown in FIG. 8). Two example implementations including photonic interposers and chiplets are shown in FIGS. 6-7. Both implementations include a photonic interposer 600 disposed on a substrate 100. One or more electrical chiplets 120 are disposed on the photonic interposer 600, and communicate with the photonic interposer via optical transceivers 612 (coupled to waveguide 614). One or more photonic chiplets 110 are disposed in a recess formed in the substrate, similar to the arrangement of FIG. 1A. In the implementation of FIG. 6, a waveguide 114 of the photonic chiplet 110 is optically coupled to a waveguide 614 of the photonic interposer 600 (e.g., via evanescent coupling). In the implementation of FIG. 7, the photonic chiplet 110 is electrically coupled to the photonic interposer 600 (e.g., via metal bumps 722). While FIG. 6 and FIG. 7 illustrate examples where the photonic chiplet 110 is coupled to the photonic interposer 600 either optically or electrically, respectively, in some embodiments the photonic chiplet 110 may be coupled to the photonic interposer 600 both optically and electrically. In any of the aforementioned implementations, having a photonic chiplet formed in a recess of the substrate enables optical access from any direction. As a result, the package may provide optical access to the photonic interposer from the north-south direction and optical access to the photonic chiplet from the west-east direction. FIG. 8 is a top view of the package of FIG. 6. In this example, a first fiber 104 extending in the north-south direction is coupled directly to photonic interposer 600, while another fiber 104 is coupled to photonic chiplet (and consequently, to interposer 600) in the west-east direction.

As discussed above in connection with FIG. 1A, the photonic chiplets 110 of FIGS. 6-8 may be positioned to have an edge flush with the outer edge of substrate 100. Alternatively, photonic chiplet 110 may be positioned to have an edge extending over the outer edge of substrate 100 (as described above in connection with FIG. 2). Yet alternatively, photonic chiplet 110 may be positioned to have an edge extending inside the outer edge of substrate 100. In some embodiments, a ridge similar to ridge 133 of FIG. 1A may be included.

Having thus described several aspects and embodiments of the technology of this application, it is to be appreciated that various alterations, modifications, and improvements will readily occur to those of ordinary skill in the art. Such alterations, modifications, and improvements are intended to be within the spirit and scope of the technology described in the application. It is, therefore, to be understood that the foregoing embodiments are presented by way of example only and that, within the scope of the appended claims and equivalents thereto, inventive embodiments may be practiced otherwise than as specifically described.

In addition, any combination of two or more features, systems, articles, materials, and/or methods described herein, if such features, systems, articles, materials, and/or methods are not mutually inconsistent, is included within the scope of the present disclosure.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The terms “approximately” and “about” may be used to mean within ±20% of a target value in some embodiments, within ±10% of a target value in some embodiments, within ±5% of a target value in some embodiments, and yet within ±2% of a target value in some embodiments.

The terms “approximately” and “about” may include the target value.

What is claimed is:

1. A package comprising:
a substrate having a recess defined near an edge of the substrate;
a photonic chiplet disposed in the recess;
an electrical chiplet disposed at least in part on the photonic chiplet; and
a fiber optically coupled to the photonic chiplet at the edge of the substrate.

2. The package of claim 1, wherein a portion of the photonic chiplet overhangs the substrate.

3. The package of claim 1, further comprising one or more connections coupling a top surface of the substrate to a top surface of the photonic chiplet.

4. The package of claim 1, wherein the photonic chiplet comprises a through silicon via (TSV) coupled to the substrate.

5. The package of claim 1, wherein the electrical chiplet is disposed in part on the photonic chiplet and in part on the substrate.

6. The package of claim 1, wherein the photonic chiplet has a top surface that is less than 30 mm×40 mm.

7. A package comprising:
a substrate having a recess;
a photonic chiplet disposed in the recess;
a photonic interposer disposed on the substrate; and
an electrical chiplet disposed at least in part on the photonic interposer,
wherein the photonic chiplet is coupled to the photonic interposer electrically or optically.

8. The package of claim 7, wherein the photonic interposer covers at least partially the photonic chiplet.

9. The package of claim 7, further comprising a first fiber coupled to the photonic interposer and a second fiber coupled to the photonic chiplet.

10. The package of claim 9, wherein the first fiber and the second fiber extend in directions orthogonal to each other.

11. The package of claim 7, wherein the photonic chiplet is optically coupled to the photonic interposer via evanescent coupling.

12. The package of claim 7, wherein the photonic chiplet is electrically coupled to the photonic interposer via metal bumps.

13. A package comprising:
a substrate having a first recess defined near a first edge of the substrate and a second recess defined near a second edge of the substrate;
a first photonic chiplet disposed in the first recess and a second photonic chiplet disposed in the second recess; and
a first fiber optically coupled to the first photonic chiplet at the first edge of the substrate and a second fiber optically coupled to the second photonic chiplet at the second edge of the substrate.

14. The package of claim 13, wherein the first edge is orthogonal to the second edge.

15. The package of claim 13, further comprising an electrical chiplet disposed at least in part on the first photonic chiplet.

16. The package of claim 15, wherein the electrical chiplet is disposed at least in part on the second photonic chiplet.

17. The package of claim 13, further comprising:
a first V-groove, disposed in the first recess, coupling the first fiber to the first photonic chiplet; and
a second V-groove, disposed in the second recess, coupling the second fiber to the second photonic chiplet.

18. The package of claim 13, wherein a portion of the first photonic chiplet overhangs the substrate.

19. The package of claim 13, wherein the first photonic chiplet comprises a through silicon via (TSV) coupled to the substrate.

20. The package of claim 13, further comprising one or more connections coupling a top surface of the substrate to a top surface of the first photonic chiplet.
